(19) United States
(12) Patent Application Publication
(10) Pub. No.: US 2010/0148809 A1
(43) Pub. Date: Jun. 17, 2010

(54) PROBE CARD FOR TESTING SEMICONDUCTOR DEVICE, PROBE CARD BUILT-IN PROBE SYSTEM, AND METHOD FOR MANUFACTURING PROBE CARD

(76) Inventor: Jong Su KIM, Gyeonggi-do (KR)

Correspondence Address: LADAS & PARRY LLP, 224 SOUTH MICHIGAN AVENUE, SUITE 1600, CHICAGO, IL, 60604, US

(21) Appl. No.: 12/494,372

(22) Filed: Jun. 30, 2009

(30) Foreign Application Priority Data
Dec. 12, 2008 (KR) 10-2008-0126444

(51) Int. Cl. G01R 31/02; G01R 1/067; H01L 21/3205

(52) U.S. Cl. 324/754; 438/674; 257/E21.295

(57) ABSTRACT

A probe card is includes a wafer and a plurality of needle patterns penetrating the wafer. The needle patterns are configured to supply an electrical signal for testing a separate wafer. The probe card may be mounted to a printed circuit board in a manner in which conductive patterns of the probe card are electrically connected to conductive terminals of the printed circuit board. The needle patterns may protrude from a lower end of the wafer and be formed so that an interval between needle patterns is the same as an interval between pads of a wafer to be tested.

### CROSS-REFERENCES TO RELATED PATENT APPLICATION

The present application claims priority under 35 U.S.C 119(a) to Korean Application No. 10-2008-0126444, filed on Dec. 12, 2009, in the Korean Intellectual Property Office, which is incorporated herein by reference in its entirety as set forth in full.

### BACKGROUND

1. Technical Field

Embodiments herein relate generally to an apparatus for testing a wafer, and more particularly, to a probe card for testing a wafer, and a method for manufacturing the same.

2. Background

Over the years the level of integration of the semiconductor integrated circuit has increased exponentially. In order to achieve high integration the cell area as well as the area of the peripheral region has been reduced in order to increase the number of net dies formed on the wafer. Although the size of the semiconductor integrated circuit has reduced, the number of pads used as transfer paths for external signals in the semiconductor integrated circuit has increased, while the number of power pads has been reduced.

Meanwhile, the exposed area of a pad for connection has also been minimized to facilitate the increase in integration of the semiconductor integrated circuit. If the exposed area is reduced, an interval (pitch) between probe needles is larger than a pad pitch for testing the probe, such that the probe, which is used in a subsequent die test, cannot be accurately tested.

As known, in order to evaluate the performance of the semiconductor integrated circuit, a die test is performed on a wafer on which the semiconductor integrated circuit is manufactured prior to shipping in order to determine whether the wafer is good or not (that is, to determine whether the wafer is defective). In further detail, the die test is an electrical die sorting test(EDS), and the EDS test is performed by a probe system. The probe system tests whether a chip performs as designed. In the EDS test, the probe needle of the probe card contacts the pad of the chip, and current is applied to the chip pad from the probe needle. A determination is made as to whether the chip is defective or not by evaluating the output characteristics of the chip.

However, in a typical probe system, the probe needle contacts the wafer pad when performing the electrical test, and as a consequence, a scratch can occur during the process of contacting the probe needle to the wafer pad. During this process, the pad surface gets stripped off causing undesirable by-products.

Further, the test should be performed for each pad of the semiconductor chip, and the time needed to perform such a test is therefore long.

In addition, it may be desirable to test a plurality of pads simultaneously. However, the interval between the probe needles must be controlled properly to correspond to the interval between pads, or else test reliability can be diminished.

### SUMMARY

In an embodiment of the present invention includes a probe card includes a wafer and a plurality of needle patterns formed inside the wafer so as to penetrate through the wafer.

Further, a probe system according to an embodiment includes: a probe card that includes a wafer, a plurality of needle patterns penetrating through the inside of the wafer and being protruded to the outside of one side surface of the wafer by a predetermined length, and a conductive pattern formed on the other side surface of the wafer while being electrically connected to each of the needle patterns; and a printed circuit board that is mounted to be electrically connected to the conductive pattern of the probe card.

Moreover, a method for manufacturing a probe card according to another embodiment includes: preparing a wafer; forming a plurality of trenches in the wafer at a predetermined interval; forming needle patterns by filling a conductive material in the trenches; and exposing the needle patterns by grinding a rear of the wafer.

These and other features, aspects, and embodiments are described below in the period “Detailed Description.”

### BRIEF DESCRIPTION OF THE DRAWINGS

Features, aspects, and embodiments are described in conjunction with the attached drawings, in which:

FIG. 1 is a cross-sectional view showing a probe card according to an embodiment of the present invention;

FIG. 2 is a cross-sectional view showing a probe system according to an embodiment of the present invention;

FIG. 3 is a cross-sectional view shown for explaining a method for testing a pad using a probe system according to an embodiment of the present invention; and

FIGS. 4 to 8 are cross-sectional views shown for illustrating a method for manufacturing a probe card according to the embodiment.

### DETAILED DESCRIPTION

Hereinafter, an exemplary embodiment of the present invention will be described with reference to the accompanying drawings.

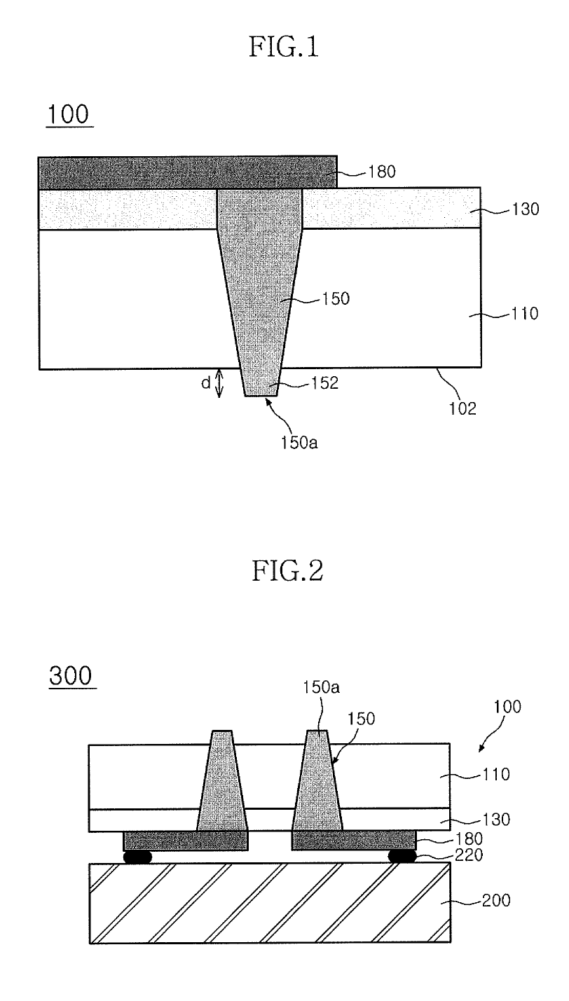

Referring to FIG. 1, a probe card 100 can be configured to include a wafer 110 and a plurality of needle patterns 150. The respective needle patterns 150 penetrate through the width of the wafer 110 and protrude from a lower surface 102 of the wafer 110 by a predetermined length.

As the wafer 110, various shapes and types of semiconductor wafers may be used, such as a silicon (Si) wafer, a gallium arsenic (GaAs) wafer, and silicon on insulator (SOI) wafer, etc.

In an embodiment, the needle pattern 150 is composed of a low resistance material, such as aluminum (Al), lead (Pb), tungsten (W), gold (Au), or copper (Cu), etc., each of which is a conductive material. Further, in an embodiment the diameter of the needle pattern 150 gradually decreases as the needle pattern extends toward the protruding lower end, and the surface 150a of at the end of the protruding portion of the needle pattern 150 is formed so as to have a smaller diameter than the remaining needle pattern 150. At this time, the length ‘d’ of the protruding portion 152 of the needle pattern 150, that is, the length from the lower surface of the wafer 110 to the surface 150a of the protruded surface of the needle pattern 150, is set so as be smaller than the thickness of a typical semiconductor pad (not shown).

A conductive pattern 180 for providing an electrical signal to the needle pattern 150 is disposed on the upper surface of the wafer 110. The conductive pattern 180 contacts an external electrical connection medium (for example, a conductive pattern of a printed circuit board as described below) to provide the electrical signal to the needle pattern 150. The conductive pattern 180 is configured to extend in a predetermined direction from the point at which it contacts the needle pattern 150 in order to facilitate electrical connection with a printed circuit board (not shown), and can have an area larger than that of the surface of the needle pattern 150 on which the conductive pattern 180 is disposed.

In order to prevent the occurrence of an electrical short circuit between the conductive pattern 180 and the wafer 110, an embodiment includes a buffer layer 130 disposed on the upper surface of the wafer 110 and interposed between the conductive pattern 180 and the wafer 110. The buffer layer 130 can use a passivation material that can prevent moisture and foreign materials from being permeated.

The probe card 100 is mounted on a printed circuit board 200, making it possible to configure a probe system 300.

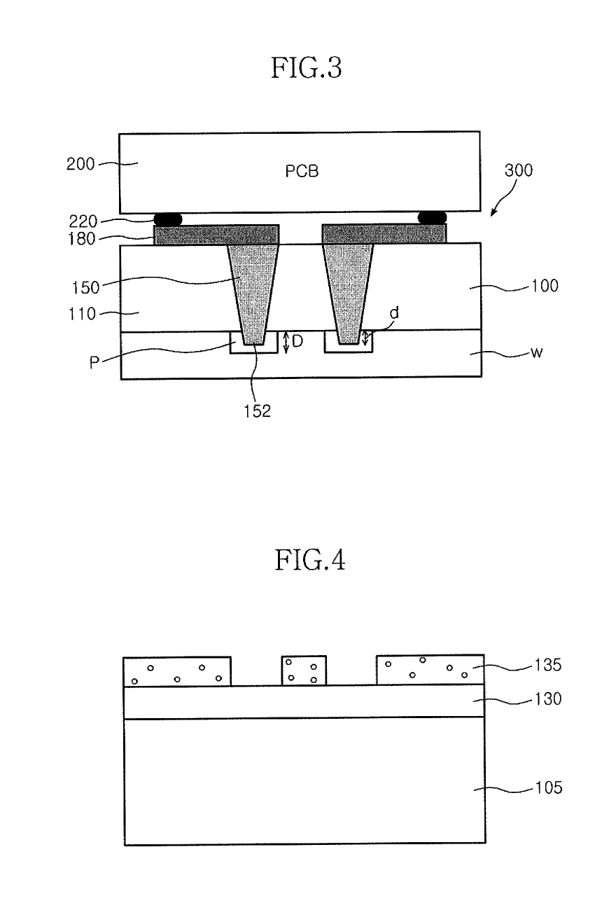

Referring to FIG. 2, the probe system 300 according to an embodiment of the present invention includes the printed circuit board 200 and the probe card 100 in wafer form and mounted on the upper portion of the printed circuit board 200.

A conductive terminal 220 for electrical connection, for example, a ball or a bump, is formed on one surface of the printed circuit board 200, and the probe card 100 is mounted on the printed circuit board 200 so that the conductive pattern 180 of the probe card 100 is connected to the conductive terminal 220 of the printed circuit board 200.

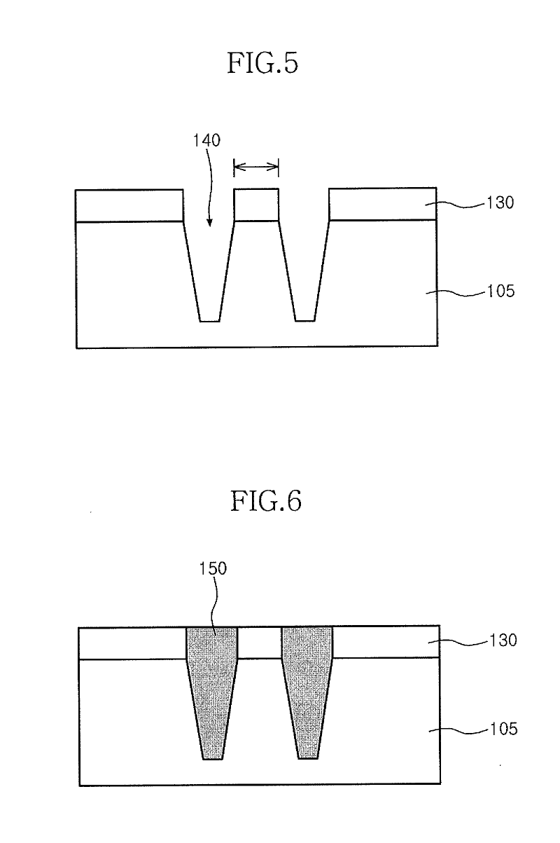

Referring to FIG. 3, the probe system 300 is mounted so that the protruded portion 152 of the needle pattern 150 contacts a pad ‘p’ of a wafer ‘w’ to be tested, in order that the electrical characteristics of the wafer can be tested. The probe system 300 is removably mounted so that the probe may be removed upon completion of testing

At this time, the interval between the needle patterns 150 of the probe card 100 is determined in consideration of the interval between the pads ‘p’. Preferably, the interval between the needle patterns 150 is set so that the needle patterns 150 of the probe card 100 can contact two adjacent pads ‘p’, respectively. In order to achieve the desired interval, in an embodiment the probe card 100 and the pads on the wafer to be tested are manufactured through the same exposure equipment at wafer level, such that the interval between the needle patterns 150 can be sufficiently controlled to be the same as the interval between the pads ‘p’.

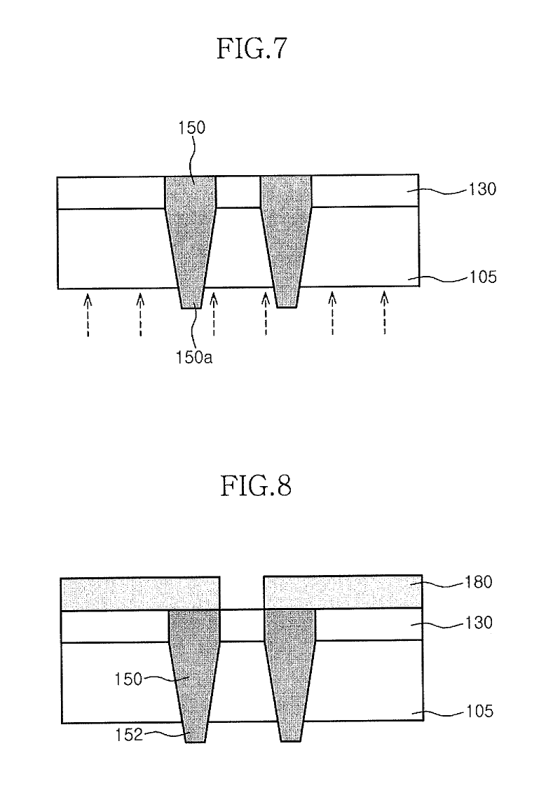

A method for manufacturing the probe card according to an embodiment of the present invention will be described with reference to FIGS. 4 to 8.

Referring to FIG. 4, a wafer 105 is prepared and then a buffer layer 130 is formed on one surface of the wafer 105. The wafer 105 can be, for example, a semiconductor wafer having a predetermined conductive type. The buffer layer 130 is formed to electrically insulate the wafer 105 from a subsequently formed conductive layer and further protects the surface of the wafer 105. A photo resist pattern 135 for forming the needle patterns is formed on the upper portion of the buffer layer 130 by a photolithography process. In an embodiment, the photo resist pattern 135 for forming the needle patterns is formed using a reticle (or a mask, not shown) that is used in forming the pad ‘p’ (see FIG. 3) on the wafer to be tested. The interval between the pads ‘p’ is the same as the interval of the needle pattern. That is, the reticle used to form the pads is also used to form holes in the photo resist pattern, and in this manner, the needle patterns, which are subsequently formed, can have the same interval as that of the pads.

Thereafter, as shown in FIG. 5, a trench 140 having a predetermined depth in the wafer 105 is formed by etching the buffer layer 130 and the wafer 105 using the photo resist pattern (not shown). When etching the trench 140, the depth of the wafer controls the transfer of etching gas so that the etching gas will not be easily transferred as the etching depth inside of the wafer 105 increases 105, allowing the diameter of the trench 140 to be gradually reduced when extending towards the lower portion of the wafer 105. Thereafter, the photo resist pattern is removed by a known method. The adjacent trenches 140 maintain the interval between the adjacent pads on the wafer to be tested. Herein, the portion of the needle pattern 150 that will be formed at the lower end of the trench 140 is the portion of the needle pattern 150 that will be in contact with the pad ‘p’ during later testing, and is thus called the contact portion 150a.

Referring to FIG. 6, a conductive material having high conductivity is formed on the wafer 105 so that the trench 140 can be sufficiently filled. Examples of conductive materials having high conductivity and suitable for use as a needle pattern include, for example, aluminum (Al), lead (Pb), tungsten (W), and copper (Cu). The conductive material is planarized to expose the surface of the buffer layer 130 to form the needle pattern 150 in the trench 140. In an embodiment, the conductive material can be chemically and mechanically polished to carry out planarization.

Next, as shown in FIG. 7, the rear of the wafer 105 on which the needle pattern 150 is formed is grinded. Preferably, the rear of the wafer 105 is grinded so that the side wall of the respective needle patterns 150 are exposed by a predetermined length from the contact portion 150a of the needle pattern 150. Reference numeral 110 indicates the grinded wafer and the portion of needle pattern 150 towards the lower end of the wafer 105 protrudes from the wafer by a predetermined length as a result of the grinding process. Reference numeral 152 indicates the protruded portion of the needle pattern 150. At this time, the length ‘d’ of the protruded portion 152 of the needle pattern 150 should be less than the thickness ‘D’ of the pad ‘p’ to be tested.

Next, referring to FIG. 8, the conductive layer is formed on the upper portion of the buffer layer 130 so that it is coupled to the needle pattern 150. The conductive layer is then patterned to form a conductive pattern that extends in a predetermined direction while being coupled to the needle pattern 150. Extending the conductive pattern 180 in a predetermined direction facilitates the subsequent electrical connection to the printed circuit board.

As described in detail, according to an embodiment of the present invention, a needle patterns are formed to have an interval therebetween that is the same as that of pads formed in a wafer to be tested, making it possible to test the electrical characteristic of the pads.

Therefore, a testing error causes by a difference in the interval between needle patterns and the interval between wafer pads can be prevented, and a plurality of pads can be tested simultaneously to significantly reduce the test time.

In addition, the probe card of the embodiment can simultaneously measure the general pad and the test pad formed for the specific purpose for testing, making it possible to reduce the time consumed for separate tests. The embodiment is not limited to the foregoing embodiment.

Although the embodiment describes the needle pattern to test two adjacent pads, the embodiment is not limited solely thereto.

While certain embodiments have been described above, it will be understood that the embodiments described are by way of example only. Accordingly, the device and method described herein should not be limited based on the described embodiments. Rather, the devices and methods described herein should only be limited in light of the claims that follow when taken in conjunction with the above description and accompanying drawings.

What is claimed is:

1. A probe card for testing a semiconductor device comprising:
a wafer; and
a plurality of needle patterns configured to supply an electrical signal for testing, the needle patterns being formed inside the wafer such that the respective needles penetrate through the wafer.

2. The probe card according to claim 1, wherein an interval between adjacent needle patterns is the same as an interval between pads formed on a wafer to be tested.

3. The probe card according to claim 1, wherein the needle pattern protrudes a predetermined length from a lower end of the wafer.

4. The probe card according to claim 3, wherein the length the needle pattern protrudes is less than the thickness of the pad formed on the wafer to be tested.

5. The probe card according to claim 3, wherein the diameter of the needle pattern decreases as the needle pattern extends towards the protruding portion.

6. The probe card according to claim 1, wherein the needle pattern comprises any one of aluminum (Al), lead (Pb), tungsten (W), gold (Au), and copper (Cu).

7. The probe card according to claim 1, further comprising a conductive pattern disposed over an upper surface of the wafer and electrically connected to the needle pattern.

8. The probe card according to claim 7, further comprising a buffer layer interposed between the conductive pattern and the upper surface of the wafer.

9. The probe card according to claim 8, wherein the buffer layer is a passivation layer.

10. A probe system, comprising:
a probe card comprising:
a wafer;
a plurality of needle patterns configured to supply an electrical signal for testing, the needle patterns being formed inside the wafer such that the respective needle patterns penetrate through the inside of the wafer, wherein the respective needle patterns protrude a predetermined length outside of a first surface of the wafer; and
a conductive pattern formed on a second surface of the wafer and electrically connected to the needle patterns; and
a printed circuit board mounted so as to be electrically connected to the conductive pattern of the probe card.

11. The probe system according to claim 10, wherein the printed circuit board comprises a conductive terminal electrically connected to the conductive pattern.

12. The probe system according to claim 11, wherein the conductive terminal is a conductive ball or a conductive bump.

13. The probe system according to claim 10, wherein the probe card further comprises a buffer layer interposed between the conductive pattern and the wafer.

14. The probe system according to claim 10, wherein the conductive pattern extends along the wafer in a predetermined direction from a point at which a portion of the conductive pattern contacts a needle pattern to facilitate electrical connection to the printed circuit board.

15. The probe system according to claim 10, wherein an interval between needle patterns is the same as an interval between pads on a wafer to be tested.

16. A method for manufacturing a probe card for testing a semiconductor device, the method comprising:
providing a wafer;
forming a plurality of trenches in the wafer such that the trenches are spaced from each other by a predetermined interval;
filling the trenches with a conductive material to form needle patterns for supplying an electrical signal for testing; and
grinding a rear surface of the wafer to expose the needle patterns.

17. The method for manufacturing a probe card according to claim 16, wherein the exposing the needle pattern comprises grinding a rear surface of the wafer such that the respective needle patterns protrude a predetermined length from the wafer.

18. The method for manufacturing a probe card according to claim 16, further comprising forming a buffer layer on the upper portion of the wafer between preparing the wafer and forming the trench on the wafer.

19. The method for manufacturing a probe card according to claim 16, further comprising:
after exposing the needle patterns, forming a conductive pattern on the upper portion of the wafer such that the conductive pattern is electrically connected to the needle pattern.

20. The method for manufacturing a probe card according to claim 16, further comprising forming a photoresist pattern on the wafer, the wafer exposing portions of wafer at which the trenches are formed, wherein the exposure equipment used to form the photoresist pattern is the same as that used to form pads of a wafer to be tested by the probe card.
